(19) United States
(12) Patent Application Publication
(10) Pub. No.: US 2009/0305505 A1
(43) Pub. Date: Dec. 10, 2009

(54) METHOD FOR MANUFACTURING A SEMICONDUCTOR DEVICE

(75) Inventors: Sa Ro Han PARK, Gyeonggi-do (KR); Tae Seung Eom, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/346,368

(22) Filed: Dec. 30, 2008

(30) Foreign Application Priority Data
Jun. 9, 2008 (KR) 10-2008-0053718

(51) Int. Cl. H01L 21/311

(52) U.S. Cl. 438/694; 257/E21.249

(57) ABSTRACT

A method for manufacturing a semiconductor device includes forming a plurality bar patterns over an underlying layer. A spacer is formed at both sides of the bar patterns and the bar patterns are removed. The spacers are isolated by an exposing process to form a vernier pattern. The underlying layer is etched using the vernier pattern as an etching mask.

### CROSS-REFERENCE TO RELATED APPLICATION

The priority benefit of Korean patent application number 10-2008-0053718, filed on Jun. 9, 2008, is claimed and the disclosure thereof is incorporated by reference in its entirety.

### BACKGROUND OF THE INVENTION

The present invention generally relates to a method for manufacturing a semiconductor device, and more specifically, to a plurality of spacers having a bar shape are formed over a semiconductor substrate, and the spacers and the semiconductor substrate are etched with a mask to define a mother vernier, thereby obtaining the mother vernier.

A complicated process using a plurality of overlapped exposure masks is performed on a high-integrated semiconductor device. The exposure masks used in each step of a photolithography process are arranged based on a mark having a specific shape.

The mark includes a layer-to-layer alignment mask, an alignment key or an alignment mark used in alignment between dies per mask, and an overlay measuring mark for measuring overlay vernier (i.e., overlay accuracy) between patterns.

The overlay accuracy represents an alignment state between upper and lower patterns, and serves as an important variable depending on the high-integrated device. The overlay accuracy is measured using the overlay vernier.

The overlay vernier includes a mother vernier formed in a lower layer deposited in a previous process, and a child vernier formed in an upper layer deposited in a current process.

In order to measure the arrangement, a pattern for measuring overlay is additionally formed in the semiconductor structure. The overlay pattern is fabricated to have a box-in-box shape.

The box-in-box shaped overlay pattern is fabricated with an outer box and an inner box, which is smaller than the outer box. The outer box and the inner box are formed in lower and upper layers, respectively, so that the accuracy between the two layers can be measured through the overlay of the boxes.

An overlay margin of the outer box and the inner box is measured in the manufacturing process. The measured overlay value is regulated to align the photoresist pattern in the lower structure.

Since it is important to overlay a recess gate for isolation, a pin gate and gate patterns with a cut region, it is also important to form a mother vernier which is capable of overlay reading.

However, in a conventional method for manufacturing a semiconductor device, an etching process using an etch mask is performed to etch the spacer pattern, so that it is impossible to form the mother vernier which is capable of overlay reading.

### SUMMARY OF THE INVENTION

Various embodiments of the present invention are directed at providing a method for manufacturing a semiconductor device. The method comprises: forming a plurality of bar type spacers over a semiconductor substrate; and etching the spacer and the semiconductor substrate using a mask to define a mother vernier.

According to an embodiment of the present invention, a method for manufacturing a semiconductor device comprises: forming a plurality of bar patterns over an underlying layer; forming a spacer at both sides of the bar patterns; removing the bar patterns; isolating the spacers by an exposing process to form a vernier pattern; and etching the underlying layer using the vernier pattern as an etching mask.

The underlying layer includes a semiconductor substrate.

A hard mask layer is formed over the semiconductor substrate.

The bar pattern includes a carbon layer.

The spacer includes a nitride film.

The spacers are isolated by an exposing process using a mask that exposes a central portion of the spacers.

The vernier pattern includes internal and external patterns.

The vernier pattern includes a plurality of segments.

Each of the segments is formed to have a size ranging from 0.05 to 10 μm.

The method may further include forming an insulating film over the underlying layer but not over the vernier pattern after etching the underlying layer.

The plurality of bar patterns are arranged collectively to form a ring shape, and a longitudinal direction of each of the plurality of bar patterns intersects the ring shape.

### BRIEF DESCRIPTION OF THE DRAWINGS

FIGS. 1a to 1g are plane views illustrating a method for manufacturing a semiconductor device according to an embodiment of the present invention.

### DETAILED DESCRIPTION OF SPECIFIC EMBODIMENT

The present invention will be described in detail with reference to the drawings. In the drawings, the thickness of layers and regions is exaggerated for accuracy, and a layer can be directly formed over a different layer or a substrate or a third layer can be formed between the different layer and the substrate. The same reference numbers represent the same components.

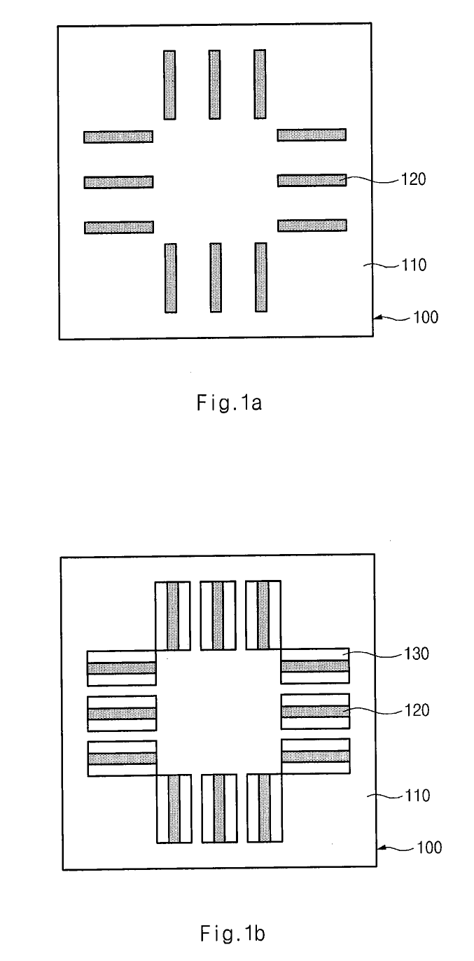

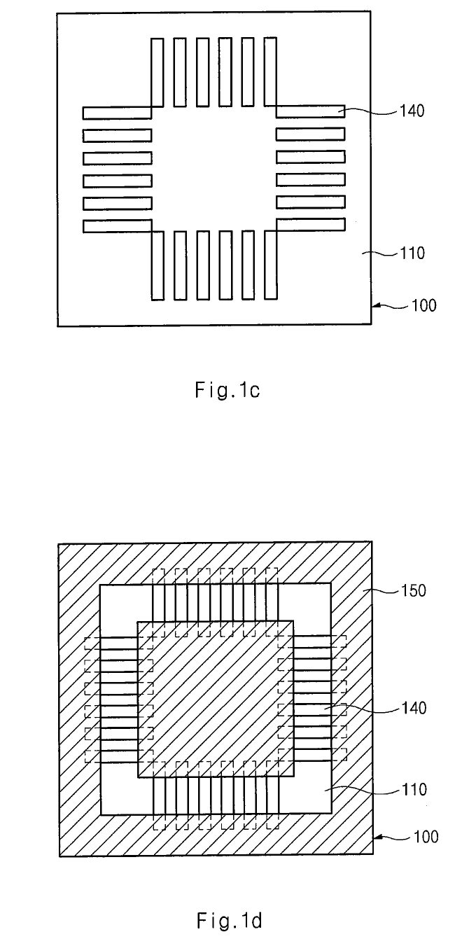

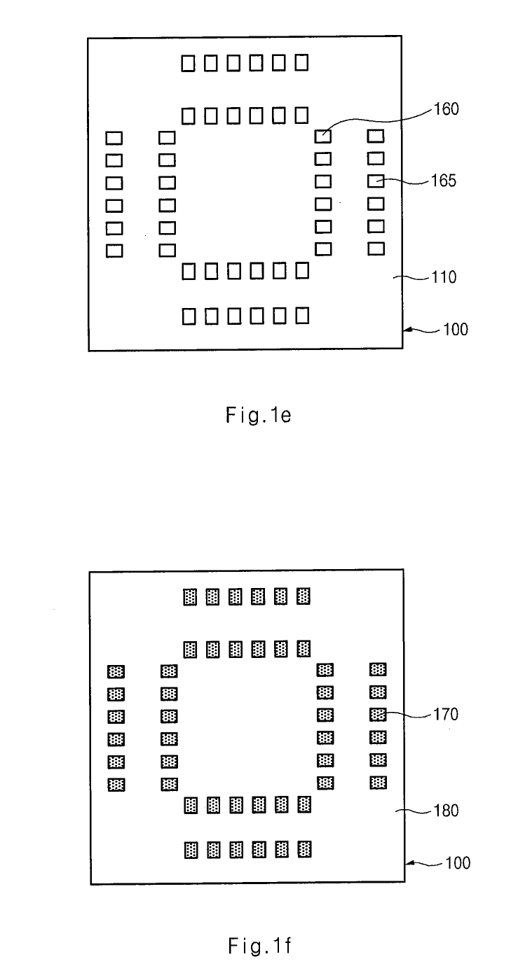

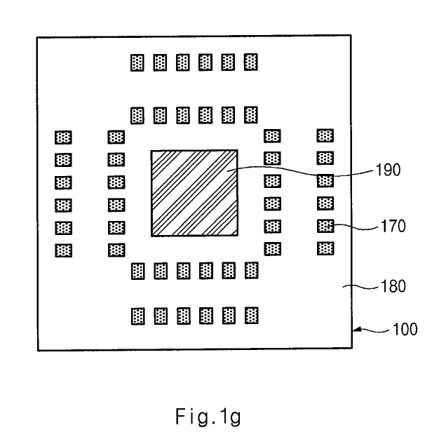

FIGS. 1a to 1g are plane views illustrating a method for manufacturing a semiconductor device according to an embodiment of the present invention.

Referring to FIG. 1a, a hard mask layer 110 and a sacrificial layer (not shown) are formed over a semiconductor substrate 100. A photoresist film is formed over the sacrificial layer that includes a carbon layer. An exposing and developing process is performed with a bar-type mask to form a photoresist pattern (not shown).

The sacrificial layer is etched using the photoresist pattern as a mask to form a bar pattern 120 including a plurality of longitudinally extending bars. Each bar of the bar pattern 120 extends longitudinally outward toward a periphery of the semiconductor substrate 100. The bar pattern 120 is formed over the hard mask layer 110 at a middle portion of each side of a square of the semiconductor substrate 100. The bar pattern 120 is not formed near corners of the semiconductor substrate 100.

A spacer material (not shown) is formed over the resulting structure including the bar pattern 120. The spacer material includes a nitride film.

Referring to FIG. 1b, the spacer material is etched to form a spacer 130 at sidewalls of each bar of the bar pattern 120.

Referring to FIG. 1c, the bar pattern 120 is removed by a strip process, thereby obtaining a spacer pattern 140 having a plurality of bar shaped spacers. The spacer pattern 140 is denser than the bar pattern 120.

Referring to FIG. 1d, a photoresist film is formed over the resulting structure including the spacer pattern 140. A photoresist pattern 150 is formed by an exposing and developing process using a box and ring shaped mask that exposes a central portion of each bar shaped spacer of the spacer pattern 140.

Referring to FIG. 1e, the spacer pattern 140 is etched with the photoresist pattern 150 as a mask to form an internal vernier pattern 160 and an external vernier pattern 165.

The internal and external vernier patterns 160 and 165 include the given number of segments each including a nitride film. The segment is formed to have a size ranging from 0.05 μm to 10 μm.

Referring to FIGS. 1f and 1g, the hard mask layer 110 and the semiconductor substrate 100 are etched with the internal and external vernier patterns 160 and 165 to form a mother vernier (170). An insulating film 180 is filled around the mother vernier (170).

A child vernier pattern 190 having a pad type is formed in the center portion surrounded by the mother vernier (170).

As described above, according to an embodiment of the present invention, a method for manufacturing a semiconductor device includes: forming a plurality of bar patterns over an underlying layer; forming a spacer at both sides of the bar patterns; removing the bar patterns; isolating the spacers by an exposing process to form a vernier pattern; and etching the underlying layer using the vernier pattern as an etching mask. A plurality of spacers each having a bar shape are formed over a semiconductor substrate, and the spacers and the semiconductor substrate are etched using a mask to define a mother vernier pattern.

The above embodiments of the present invention are illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A method for manufacturing a semiconductor device, the method comprising:
forming a plurality of bar patterns over an underlying layer;
forming a spacer at both sides of the bar patterns;
removing the bar patterns;
isolating the spacers by an exposing process to form a vernier pattern; and
etching the underlying layer using the vernier pattern as an etching mask.

2. The method according to claim 1, wherein the underlying layer comprises a semiconductor substrate.

3. The method according to claim 2, wherein a hard mask layer is formed over the semiconductor substrate.

4. The method according to claim 1, wherein the bar patterns comprise a carbon layer.

5. The method according to claim 1, wherein the spacer comprises a nitride film.

6. The method according to claim 1, wherein the spacers are isolated by an exposing process using a mask that exposes a central portion of the spacers.

7. The method according to claim 1, wherein the vernier pattern includes internal and external patterns.

8. The method according to claim 1, wherein the vernier pattern includes a plurality of segments.

9. The method according to claim 8, wherein each of the segments is formed to have a size ranging from 0.05 to 10 μm.

10. The method according to claim 1, further comprising forming an insulating film over the underlying layer after etching the underlying layer, wherein the insulating film is not formed over the vernier pattern.

11. The method according to claim 1, wherein the plurality of bar patterns are arranged collectively to form a ring shape, a longitudinal direction of each of the plurality of bar patterns intersecting the ring shape.

12. A method for manufacturing a semiconductor device, the method comprising:
forming a plurality of bar patterns over a semiconductor substrate;
forming a spacer at each sides of each of the plurality of bar patterns;
removing the bar patterns;
removing a center portion of each spacer to form a vernier pattern; and
etching the semiconductor substrate using the vernier pattern as an etching mask.

13. The method according to claim 12, further comprising forming a hard mask layer over the semiconductor substrate.

14. The method according to claim 12, wherein the bar patterns comprise a carbon layer.

15. The method according to claim 12, wherein the spacer comprises a nitride film.

16. The method according to claim 12, wherein the central portions of the spacers are removed by an exposing process using a mask that exposes the central portions of the spacers.

17. The method according to claim 12, wherein the vernier pattern includes internal and external patterns, the external pattern being positioned proximate a periphery of the semiconductor substrate, the internal pattern being surrounded by the external pattern.

18. The method according to claim 12, wherein the vernier pattern includes a plurality of segments.

19. The method according to claim 18, wherein each of the segments is formed to have a size ranging from 0.05 to 10 μm.

20. The method according to claim 12, further comprising forming an insulating film over the semiconductor substrate after etching the semiconductor substrate, wherein the insulating film is not formed over the vernier pattern.

21. The method according to claim 12, wherein the plurality of bar patterns are arranged collectively to form a ring shape, a longitudinal direction of each of the plurality of bar patterns intersecting the ring shape and extending outwardly toward a periphery of the semiconductor substrate.
